(19) United States
(12) Patent Application Publication
(10) Pub. No.: US 2004/0007756 A1
(43) Pub. Date: Jan. 15, 2004

(54) Semiconductor device and fabrication method therefor

(75) Inventors: Masato Nishiyama, Hyogo (JP); Hiroshi Umeda, Hyogo (JP)

Correspondence Address: McDERMOTT, WILL & EMERY, 600 13th Street, N.W., Washington, DC, 20005-3096, US

(73) Assignee: MITSUBISHI DENKI KABUSHIKI KAISHA

(21) Appl. No.: 10/339,325

(22) Filed: Jan. 10, 2003

(30) Foreign Application Priority Data
Jul. 10, 2002 (JP) 2002-200882

(51) Int. Cl. H01L 29/76; H01L 29/94; H01L 31/062; H01L 31/113; H01L 31/119; H01L 29/00

(52) U.S. Cl. 257/506

(57) ABSTRACT

A semiconductor device of the present invention includes: a p-type silicon substrate having a main surface; a trench formed in an element isolation region on the main surface of the p-type silicon substrate; an inner wall oxide film formed on an inner wall of the trench; an oxynitride layer formed on a surface of the inner wall oxide film; and an isolation oxide film buried into the trench. On the element isolation region, there is formed a gate electrode with a gate oxide film interposed therebetween.

### BACKGROUND OF THE INVENTION

1. Field of the Invention

The present invention relates to a semiconductor device and a fabrication method therefor, and more particularly to a structure of an element isolation region isolating elements from each other in a semiconductor device and a fabrication method therefor.

2. Description of the Background Art

A trench isolation structure has been known as an element isolation structure isolating elements from each other of a semiconductor device. The trench isolation structure is obtained in a process in which a silicon substrate is etched to form a trench, the inner wall of the trench is oxidized to form an inner wall oxide film and the an oxide film is buried into the trench to thus form an isolation oxide film.

In order to improve a burying property of an oxide film in a trench, an impurity is also added into the oxide film. In this case, a requirement arises for suppression of diffusion of the impurity from the isolation oxide film into the silicon substrate.

In a fabrication process for a semiconductor device, an oxidation process is indispensable after formation of a trench isolation structure. For example, in a case where a MOS (Metal Oxide Semiconductor) transistor is formed on a main surface of a silicon substrate, the main surface of the silicon substrate is thermally oxidized to form a gate oxide film after formation of a trench isolation structure.

At this time, an oxidizing agent diffuses in a silicon oxide film in a trench to react with silicon of the inner wall of the trench and oxidize the inner wall. By the oxidation, silicon of the trench inner wall is transformed into a silicon oxide film.

When silicon is transformed into a silicon oxide film, the silicon oxide film increases in volume in comparison with that of a corresponding mass of silicon; therefore, the silicon oxide film assumes a state equivalent to expansion of a silicon oxide film buried into a trench. Therefore, an element formation region around the trench receives a compressive stress to generate crystal defects in a silicon substrate. With such defects generated, a junction leakage current increases, resulting in a problem of increase in power consumption of a semiconductor device.

On the other hand, as methods for suppressing diffusion of an impurity into a silicon substrate from an isolation oxide film, there can be exemplified a method in which thermal nitridation is applied using NO/O₂ gas, NH₃ gas or the like after formation of an inner wall oxide film and a method in which a silicon nitride film is deposited by means of a CVD (Chemical Vapor Deposition) method after formation of an inner wall oxide film. Since, according to the methods, a silicon nitride layer can be formed along an inner wall of a trench, diffusion of an impurity into a silicon substrate from an isolation oxide film can be suppressed.

When the thermal nitridation is performed, however, a silicon nitride layer is formed at an interface between a silicon substrate and an inner wall oxide film and nitridation generates on even a main surface of silicon in the vicinity of the top end portion of a trench, which is a part of an element formation region, For this reason, when a gate oxide film is formed on the main surface, the gate oxide film comes to have a local thin portion, which leads to a problem of reduction in insulation withstand voltage.

In order to effectively suppress the above described impurity diffusion by a silicon nitride film formed by means of a CVD method, a thickness of the silicon nitride film is required to be on the order of not less than 5 nm. By forming such a silicon nitride film in a trench, however, a width of the opening of a trench is reduced, leading a problem that insufficient burying occurs with ease when an oxide film is buried into the trench. This problem becomes more conspicuous with a progress in miniaturization of an element.

### SUMMARY OF THE INVENTION

The present invention has been made in order to solve the problem as described above and it is an object of the present invention to provide a semiconductor device capable of suppressing generation of crystal defects due to oxidation of a trench inner wall, suppressing a local thin portion formed in a gate oxide film and furthermore, suppressing insufficient burying of an isolation oxide film, and a fabrication method therefor.

A semiconductor device according to the present invention includes: a semiconductor substrate having a main surface; a trench formed in an element isolation region on the main surface of the semiconductor substrate; an inner wall oxide film formed on an inner wall of the trench; an oxynitride layer or nitrided oxide layer formed at a surface of the inner wall oxide film; and an isolation oxide film buried into the trench.

The above oxynitride layer is typically a layer having an Si—N bond mainly, obtained by replacing O (an oxygen atom) in an Si—O bond with N (a nitrogen atom) without containing an Si—H bond. By forming such an oxynitride layer, it can be suppressed that an oxidizing agent passes through an oxide film in a trench to reach the inner wall of the trench during oxidation in a later process step. Furthermore, diffusion of an impurity can be suppressed by the oxynitride film of even a considerably small thickness. Therefore, even in a case where an impurity is added into an isolation oxide film, it can be suppressed that an impurity diffuses into a semiconductor substrate from an isolation oxide film and in addition, insufficient burying of the isolation oxide film can be effectively suppressed.

In the trench, the oxynitride layer is spaced apart from the inner wall of the trench and extends along the inner wall of the trench. The oxynitride layer preferably has a thickness from equal to or more than 0.2 nm to equal to or less than 4 nm. The above isolation oxide film preferably contains an impurity.

A fabrication method for a semiconductor device according to the present invention includes the following steps. A trench is formed in an element isolation region of a semiconductor substrate. An inner wall of the trench is oxidized to form an inner wall oxide film. A surface of the inner wall oxide film is nitrided by means of a radical nitridation method to form an oxynitride layer. An isolation oxide film is buried into the trench.

By nitriding the surface of the inner wall oxide film by means of the radical nitridation method to form the oxynitride layer, it is possible that O (an oxygen atom) in an Si—O bond at the surface of the inner wall oxide film is replaced with N (a nitrogen atom) to form the oxynitride layer having an Si—N bond mainly, at the surface of the inner wall oxide layer. With such a structure, the above effect can be obtained. In addition to that, since the oxynitride layer is formed by the substitution reaction described above, a thickness of the oxynitride layer can be controlled with ease and can be considerably small.

In performing the radical nitridation described above, it is preferable to form the oxynitride layer while setting an electron temperature of a plasma generating nitrogen radicals to be low, e.g., from equal to or more than 1 eV to equal to or less than 1.5 eV.

The foregoing and other objects, features, aspects and advantages of the present invention will become more apparent from the following detailed description of the present invention when taken in conjunction with the accompanying drawings.

### BRIEF DESCRIPTION OF THE DRAWINGS

FIG. 1 is a sectional view of a semiconductor device in an embodiment of the present invention, taken along line I-I of FIG. 3;

FIG. 2 is a sectional view of a semiconductor device in an embodiment of the present invention, taken along line II-II of FIG. 3;

FIG. 3 is a plan view of a semiconductor device of the present invention;

FIG. 4 is a graph showing a nitrogen quantity distribution from a surface of an inner wall oxide film up to a silicon substrate;

FIGS. 5 to 15 are sectional views showing first to eleventh steps of a fabrication process of a semiconductor device of the present invention; and

FIG. 16 is a sectional view of a radical nitridation apparatus that can be used in the present invention.

### DESCRIPTION OF THE PREFERRED EMBODIMENTS

Description will be given of embodiments of the present invention below using FIGS. 1 to 16.

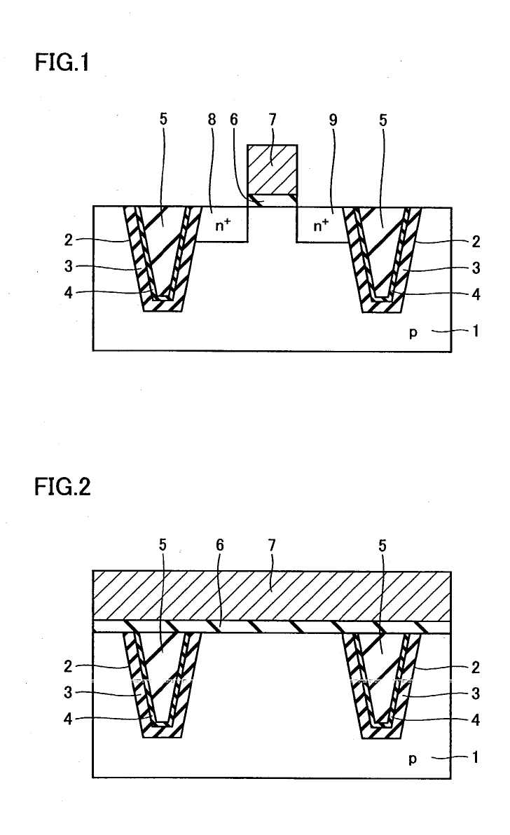

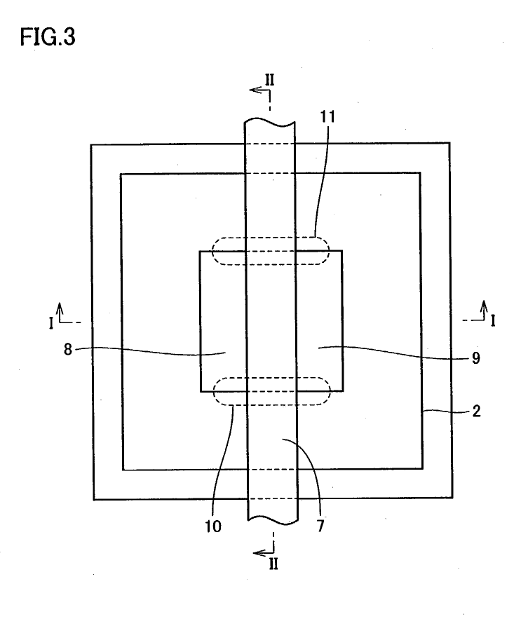

FIGS. 1 and 2 are sectional views of a semiconductor device according to an embodiment of the present invention, taken along lines I-I and II-II of FIG. 3, respectively.

As shown in FIGS. 1 to 3, a trench isolation region is formed in an element formation region on a main surface of a p-type silicon substrate (semiconductor substrate) 1 and an element such as a MOS transistor is formed on the element formation region surrounded with the trench isolation region. The MOS transistor has n-type regions 8 and 9 serving as the source/drains thereof, a gate oxide film 6, and a gate electrode 7. Note that a sidewall insulating film not shown may be formed on a side wall of the gate electrode 7.

The trench isolation region has a trench 2, an inner wall oxide film 3 formed on the inner wall of trench 2, an oxynitride layer (radical nitrided layer) 4 formed at a surface of inner wall oxide film 3, and an isolation oxide film 5 buried into trench 2.

Oxynitride layer 4 is formed by radical nitridation of the surface of inner wall oxide film 3. To be more detailed, oxynitride layer 4 can be formed in a process in which, for example, nitrogen radicals are generated in a mixed gas atmosphere composed of Ar gas and N₂ gas and O (an oxygen atom) in an Si—O bond at the surface of inner wall oxide film 3 is replaced with N (a nitrogen atom), and oxynitride layer 4 has an Si—N bond mainly.

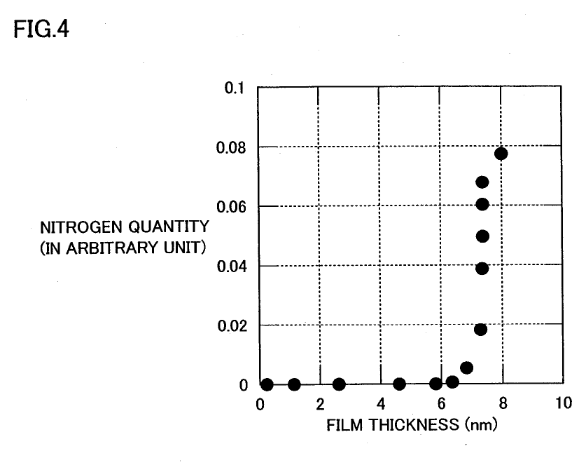

Oxynitride layer 4 is formed only at the surface of inner wall oxide film 3, but nitridation is subjected to neither a depth of inner wall oxide film 3 or silicon substrate 1. In FIG. 4, there is shown a nitrogen quantity distribution from a surface of inner wall oxide film 3 to the interior thereof in a case where inner wall oxide film 3 is nitrided. In FIG. 4, a position indicated by 0 nm on a scale of the abscissa corresponds to an interface between p-type silicon substrate 1 and inner wall oxide film 3 and a position indicated by 8 nm on the scale corresponds to the surface of oxynitride layer 4. As shown in FIG. 4, it can be seen that nitrogen resides only in a range of 1 to 2 nm in depth from the surface of inner wall oxide film 3, but no nitrogen exists at deep positions of inner wall oxide film 3 and at an interface between p-type silicon substrate 1 and inner wall oxide film 3.

Since oxynitride layer 4, as described above, is formed by nitriding only the surface of inner wall oxide film 3, a thickness of oxynitride layer 4 can be considerably small. To be concrete, a thickness of oxynitride layer 4 can be set from not less than 0.2 nm to not more than 4 nm, preferably on the order of 2 nm. Even with oxynitride layer 4 of such a small thickness, it can be suppressed that an oxidizing agent reaches to the inner wall of trench 2 during oxidation in a later process step.

Furthermore, by forming oxynitride layer 4 in a mixed gas atmosphere composed of Ar gas and N₂ gas as described above, oxynitride layer 4 contains no Si—H bond. Therefore, no problem arises that is caused by diffusion of hydrogen atoms into elements such as MOS transistor from oxynitride layer 4.

As shown in FIGS. 1 and 2, in trench 2, oxynitride layer 4 is spaced apart from the inner wall of trench 2, extends along the inner wall of trench 2, and is formed so as to cover inner wall oxide film 3.

Since, in such a way, oxynitride layer 4 is spaced apart from the inner wall of trench 2 and furthermore, as described above, silicon substrate 1 is not nitrided, no nitridation occurs in an element formation region located in the vicinity of the top end portion of the inner wall of trench 2. Therefore, even in a case where gate oxide film 6 is formed on the element formation region, it can be prevented that gate oxide film 6 has a considerably thin portion locally in the vicinity of the top end portion of the inner wall of trench 2. To be concrete, it can be suppressed that a thickness of gate oxide film 6 in regions 10 and 11 of FIG. 3 become small.

Isolation oxide film 5 preferably contains an impurity such as phosphorus (P), boron (B), fluorine (F) or the like, which improves a burying property thereof into trench 2. With such an impurity contained, even in a case where an opening width of trench 2 is reduced, isolation oxide film 5 can be buried into trench 2, thereby enabling insufficient burying of isolation oxide film 5 to be effectively suppressed.

Furthermore, even in a case where an impurity as described above is added into isolation oxide film 5, diffusion of an impurity into silicon substrate 1 from isolation oxide film 5 can be suppressed by forming oxynitride layer 4. That is, oxynitride layer 4 of the present invention functions as a barrier layer suppressing diffusion of an impurity.

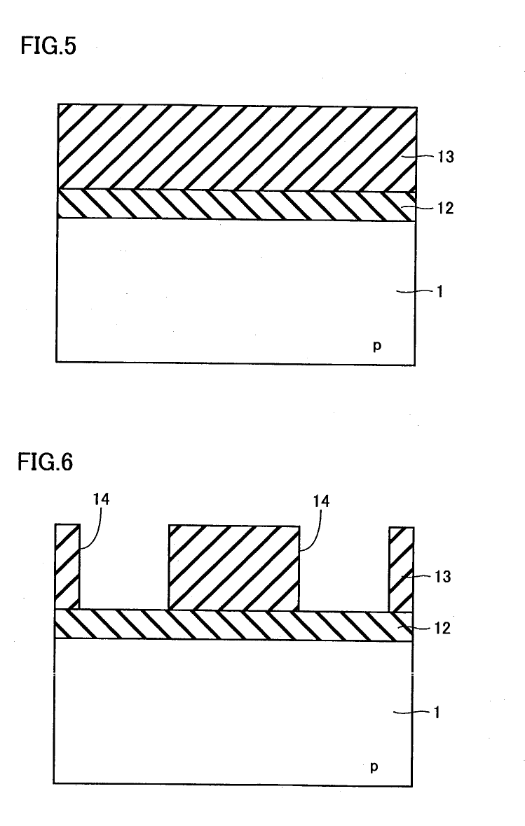

Then, description will be given of a fabrication method for a semiconductor device according to the present invention using FIGS. 5 to 16.

For example, a p-type silicon substrate 1 of 8.5 to 11.5 Ω·cm in resistivity, (100) in surface orientation, and 725 μm in thickness is thermally oxidized in a mixed gas atmosphere composed of O₂ and H₂ at 750° C. Thereby, an oxide film (silicon oxide film) 12 of 150 nm, as shown in FIG. 5, is formed on a main surface of p-type silicon substrate 1. On oxide film 12, there is deposited a silicon nitride film 13 in the range of from 100 nm to 200 nm in thickness by means of, for example, a thermal CVD method.

Then, on silicon nitride film 13, a resist (not shown) is applied and the resist coat is exposed to light and developed for patterning by means of a photolithographic technique to thereby form a resist pattern having openings corresponding to an element isolation region pattern. Anisotropic etching is performed with the resist pattern as a mask to form openings 14 in silicon nitride film 13 as shown in FIG. 6. Thereafter, the resist pattern is removed.

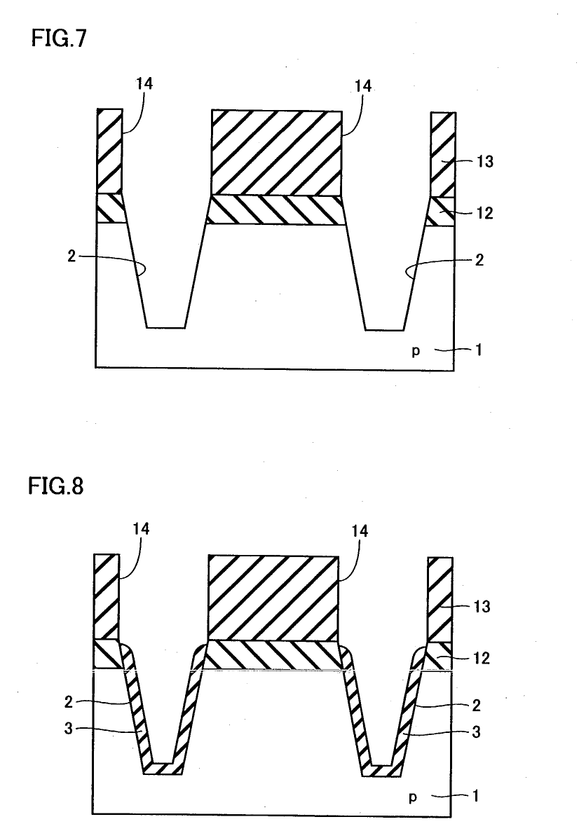

Then, oxide film 12 and p-type silicon substrate 1 are etched by means of RIE (Reactive Ion Etching) with silicon nitride film 13 as a mask using a hydrocarbon derivative gas to form trenches 2 of approximately 0.6 μm in depth as shown in FIG. 7.

Thereafter, an oxidation treatment is performed at 1000° C. for 30 sec using dry O₂ gas in, for example, a lamp annealing apparatus to oxidize the inner wall of each of trenches 2. Thereby, as shown in FIG. 8, there is formed inner wall oxide film 3 of the order in the range of 1 nm to 50 nm in thickness.

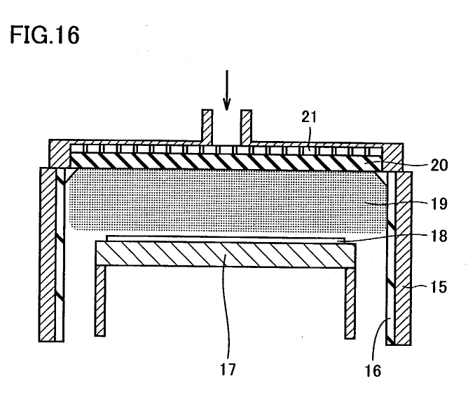

Thereafter, oxynitride layer 4 of the order of 2 nm in thickness is formed on a surface of inner wall oxide film 3 using, for example, a radical nitridation apparatus shown in FIG. 16.

Description will be given of an example construction of a radical nitridation apparatus. The radical nitridation apparatus, as shown in FIG. 16, includes a chamber 15, a heater 17, a quartz plate 20 and a slot plane antenna 21.

A quartz liner 16 is provided on the inner wall of chamber 15. A micro pulse generator (not shown) is disposed in the vicinity of chamber 15 and generates a microwave with 2.45 GHz in frequency and 5 kW in output power. The micro pulse generator and chamber 15 are connected to each other through a waveguide.

Heater 17 is, for example, an AlN heater and can heat an object to a temperature of the order of 400° C. A wafer (silicon wafer) 18 is placed on heater 17 to be heated. Slot plane antenna 21 is placed on the top end of chamber 15 and constructed of a circular copper plate with many holes therein. Quartz plate 20 is located under slot plane antenna 21.

Then, description will be given of a nitridation method (radical nitridation method) using the above radical nitridation apparatus. A micro wave generated by the micro pulse generator is propagated in the waveguide to reach the top end of chamber 15. The micro wave passes through slot plane antenna 21 to enter chamber 15.

A mixed gas of Ar gas and N₂ gas has been introduced in the interior of chamber 15 and a pressure in chamber 15 is set to a value, for example, in the range of from 66.5 Pa (500 mTorr) to 133 Pa (1000 mTorr). Nitrogen is excited by the micro wave to generate nitrogen radicals together with a plasma 19 in chamber 15. At this time an electron temperature of the plasma in which nitrogen radicals are generated is set, for example, from not less than 1 eV to not more than 1.5 eV.

Then, p-type silicon substrate 1 is heated by heater 17 at a prescribed temperature to nitride a surface of inner wall oxide film 3 with nitrogen radicals as described above to form oxynitride layer 4 of the present invention.

In the case where the radical nitridation method was performed in such a way, O (an oxygen atom) in an Si—O bond at a surface of inner wall oxide film 3 is replaced with N (a nitrogen atom) as described above to form oxynitride layer 4 having an Si—N bond mainly, therefore, it is theoretically considered that only Si—O bonds residing at the surface of inner wall oxide film 3 can be replaced with N (nitrogen atoms). Therefore, oxynitride layer 4 can be considerably thinned. Furthermore, a thickness of oxynitride layer 4 can be controlled with ease.

Furthermore, by lowering an electron temperature of a plasma generating nitrogen radicals to a low value in the range of not less than 1 eV to not more than 1.5 eV, reduction can be achieved in damage to p-type silicon substrate 1 to be caused by the plasma.

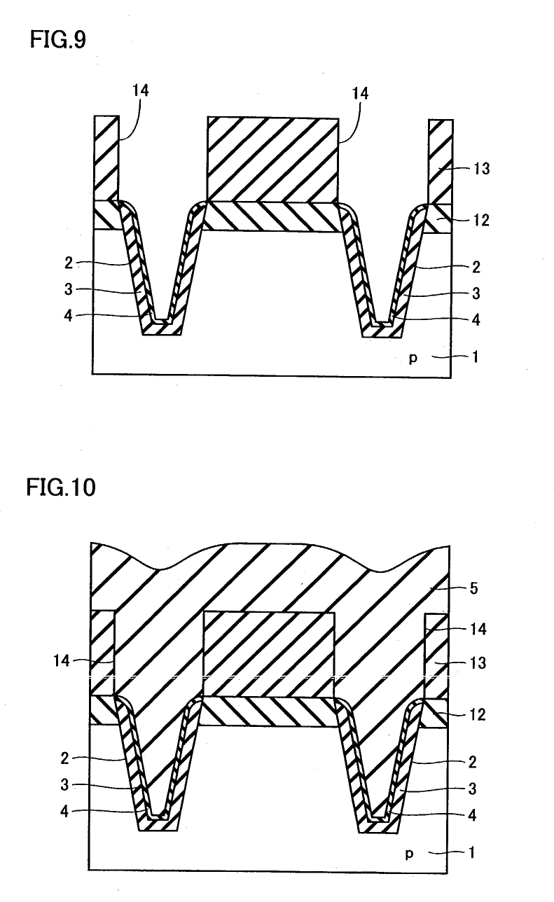

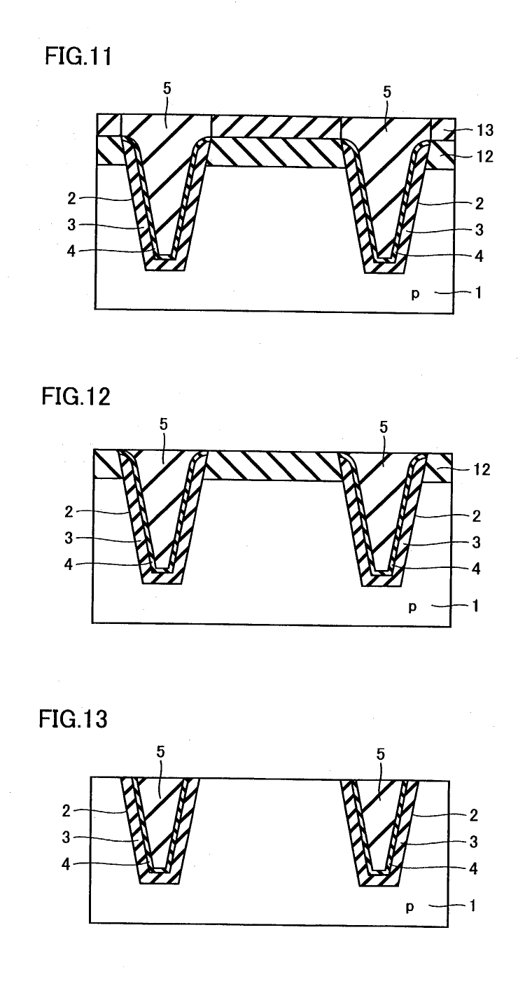

After oxynitride layer 4 is formed as described above, for example, an oxide film (F—SiO₂) containing fluorine at a content of 8% by means of a CVD method to bury the oxide film into trenches 2 as shown in FIG. 10. Thereafter, a CMP (Chemical Mechanical Polishing) treatment is applied to polish the oxide film as shown in FIG. 11. At this time, silicon nitride film 13 is used as stopper to polish off silicon nitride film 13 to a remaining thickness of the order of 10 nm.

Then, silicon nitride film 13 is removed by wet etching with, for example, phosphoric acid at 160° C. to expose oxide film 12 as shown in FIG. 12. Thereafter, boron is ion-implanted using an ion implantation apparatus three times in conditions of energy and a dosage of boron ion of respective three combinations including 250 keV and 1×10¹³/cm², 140 keV and 3×10¹²/cm², and 50 keV and 2×10¹²/cm² to form a p well in p-type silicon substrate 1.

Then, wet etching is performed with 10:1 hydrofluoric acid (HF) for 35 sec to remove oxide film 12 and to thereby, as shown in FIG. 13, expose the main surface (element formation region) of p-type silicon substrate 1.

Thereafter, for example, a sulfuric acid treatment, an ammonia-hydrogen peroxide treatment and a hydrochloric acid treatment are sequentially performed to form a chemical oxide on the main surface of p-type silicon substrate 1 and then, a natural oxide film is removed by etching using 50:1 hydrofluoric acid (HF).

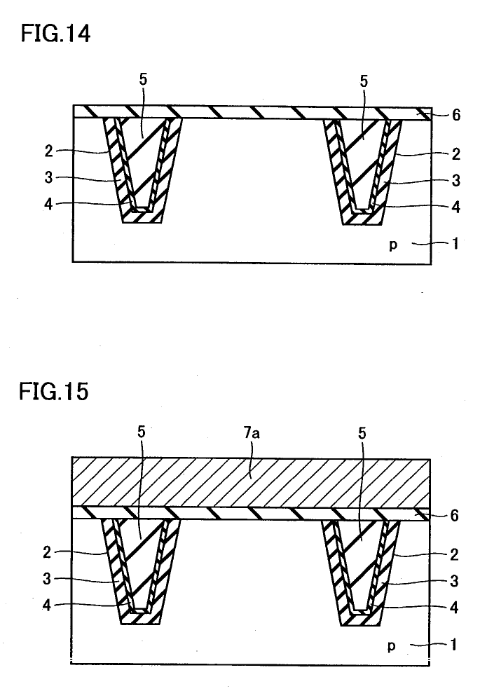

Then, the main surface (element formation region) of p-type silicon substrate 1 is thermally oxidized in conditions of 1000° C. and 30 sec using a dry O₂ gas in, for example, a lamp annealing apparatus to form gate oxide film 6 in the range of from 10 nm to 100 nm in thickness as shown in FIG. 14.

Thereafter, as shown in FIG. 15, polysilicon film 7a of 200 nm in thickness is deposited by means of a CVD method at a temperature 650° C. Polysilicon film 7a is ion-implanted with phosphorus in conditions of 30 eV in ion energy and 4×10¹⁵/cm² in dosage.

Thereafter, a TEOS (Tetra Ethyl Ortho-Silicate) oxide film is deposited on polysilicon film 7a to 700 nm. TEOS oxide film is patterned into a prescribed shape and polysilicon film 7a is then patterned using patterned TEOS oxide film as a mask. Thereby, gate electrode 7 is formed.

Thereafter, arsenic is ion-implanted into the main surface (element formation region) of p-type silicon substrate 1 in conditions of 50 eV in ion energy and 5×10¹⁴/cm² in dosage to form n-type impurity regions 8 and 9 serving as source/drain regions. Thereby, the structure shown in FIGS. 1 and 2 are obtained. Thereafter, an interlayer insulating film is formed on gate electrode 7 and a wiring step for AlCu or the like is applied to the intermediate device to finally complete a transistor. Note that another step may be adopted, wherein a sidewall insulating film is formed on the side wall of gate electrode 7 to attain n-type impurity regions 8 and 9 in a LDD (Lightly Doped Drain) structure.

Note that while in the above embodiment, as one example of an oxide film buried into trenches 2, a F containing oxide film is taken up, other oxide films can be used: PSG (Phospho Silicate Glass), BPSG (Boro-Phospho Silicate Glass), TEOS, HDP (High Density Plasma) and others.

Furthermore, a polysilicon film and a silicon oxide film can also be used instead of silicon nitride film 13. Moreover, while in the above example, inner wall oxide film 3 is formed by dry O₂ oxidation, other methods can be applied: RTO (H₂/O₂) oxidation, WET oxidation, radical oxidation, plasma oxidation and others.

According to a semiconductor device of the present invention, since an oxynitride layer is formed in a trench, it can be suppressed that an oxidizing agent reaches the inner wall of the trench during oxidation of a later process step, which can suppress increase in volume of an oxide film caused by oxidation of the inner wall of the trench by the oxidizing agent. Therefore, effective suppression can be effected on generation of a junction leakage current occurring due to the increase in volume. In addition, even in a case where an impurity is added into an isolation oxide film, it can be suppressed that an impurity diffuses into a semiconductor substrate from the isolation oxide film, which can suppress a change in impurity distribution profile in an element formation region due to the diffusion of an impurity. Furthermore, since a thickness of the oxynitride layer can be thinned, insufficient burying of an isolation oxide film can be effectively suppressed. Accordingly, there can be obtained a high reliability semiconductor device.

Since in formation of an oxynitride layer, only a surface of an inner wall oxide film is nitrided, the oxynitride layer resides in a trench and extends along the inner wall of the trench spaced apart from the inner wall thereof and it can be avoided that part of a surface of an element formation region is nitrided. Therefore, in a case where a gate oxide film is formed on an element formation region, it can also be avoided that the gate oxide film is locally thinned in the vicinity of a trench.

Even in a case where a thickness of the oxynitride layer is small, it can be suppressed that an oxidizing agent and an impurity diffuse into a semiconductor substrate from an isolation oxide film. To be concrete, when a thickness of an oxynitride layer is from not less than 0.2 nm to not more than 4 nm, the above effect can be attained.

In a case where an isolation oxide film contains an impurity such as phosphorus or boron, a burying property thereof in a trench can be improved. In this case, the above effect can be attained in addition to improvement on a burying property.

According to a fabrication method for a semiconductor device of the present invention, since a surface of an inner wall oxide film is nitrided by means of a radical nitridation method to form an oxynitride layer, a considerably thin oxynitride layer can be formed on the inner wall oxide film with a good precision. In addition by forming the oxynitride layer at a surface of the inner wall oxide film, there can be fabricated a high reliability semiconductor device as described above.

In a case where the oxynitride layer is formed while an electron temperature of a plasma generating nitrogen radicals is controlled as low as at a value in the range from not less than 1 eV to not more than 1.5 eV, reduction can be attained in damage to a semiconductor substrate from a plasma.

Although the present invention has been described and illustrated in detail, it is clearly understood that the same is by way of illustration and example only and is not to be taken by way of limitation, the spirit and scope of the present invention being limited only by the terms of the appended claims.

What is claimed is:

1. A semiconductor device comprising:
a semiconductor substrate having a main surface;
a trench formed in an element isolation region on the main surface of said semiconductor substrate;
an inner wall oxide film formed on an inner wall of said trench;
an oxynitride layer formed on a surface of said inner wall oxide film; and
an isolation oxide film buried into said trench.

2. The semiconductor device according to claim 1, wherein,
within said trench, said oxynitride layer is spaced apart from the inner wall of said trench and extends along the inner wall of said trench.

3. The semiconductor device according to claim 1, wherein
said oxynitride layer has a thickness from equal to or more than 0.2 nm to equal to or less than 4 nm.

4. The semiconductor device according to claim 1, wherein
said isolation oxide film contains an impurity.

5. A fabrication method for a semiconductor device, comprising the steps of:
forming a trench in an element isolation region of a semiconductor substrate;
oxidizing an inner wall of said trench to form an inner wall oxide film;
nitriding a surface of said inner wall oxide film by means of a radical nitridation method to form an oxynitride layer; and
burying an isolation oxide film into said trench.

6. The fabrication method for a semiconductor device according to claim 5, wherein
an electron temperature of a plasma generating nitrogen radicals is set from equal to or more than 1 eV to equal to or less than 1.5 eV to form said oxynitride layer.
